(19) United States
(12) Patent Application Publication
(10) Pub. No.: US 2014/0192449 A1
(43) Pub. Date: Jul. 10, 2014

(54) SHORT-CIRCUIT PROTECTION CIRCUIT

(71) Applicant: Naoki Shimizu, Matsumoto-city (JP)

(72) Inventor: Naoki Shimizu, Matsumoto-city (JP)

(73) Assignee: FUJI ELECTRIC CO., LTD., Kawasaki-shi (JP)

(21) Appl. No.: 14/126,308

(22) PCT Filed: Jul. 10, 2012
(86) PCT No.: PCT/JP2012/004449

§ 371 Date: Feb. 14, 2014

(30) Foreign Application Priority Data
Jul. 14, 2011 (JP) 2011-155444

(51) Int. Cl. H03K 17/081

(52) U.S. Cl. CPC H03K 17/08112
USPC 361/93.1

(57) ABSTRACT

Provided is a short-circuit protection circuit having a mask circuit which can reduce a turn-on loss of a voltage-driven type semiconductor device during turn-on operation of the voltage-driven type semiconductor device. A mask circuit (21) is provided to suspend operation of an NLU circuit (24) during turn-on operation of a voltage-driven semiconductor device (1). Accordingly, the voltage-driven type semiconductor device (1) can be driven sufficiently so that a turn-on loss can be reduced.

### TECHNICAL FIELD

This invention relates to a short-circuit protection circuit which protects a voltage-driven type semiconductor device such as an IGBT (Insulated Gate Bipolar Transistor) from breakdown when a short-circuit current flows into the voltage-driven type semiconductor device. Particularly, it relates to a short-circuit protection circuit provided with a mask circuit which can reduce a turn-on loss.

### BACKGROUND ART

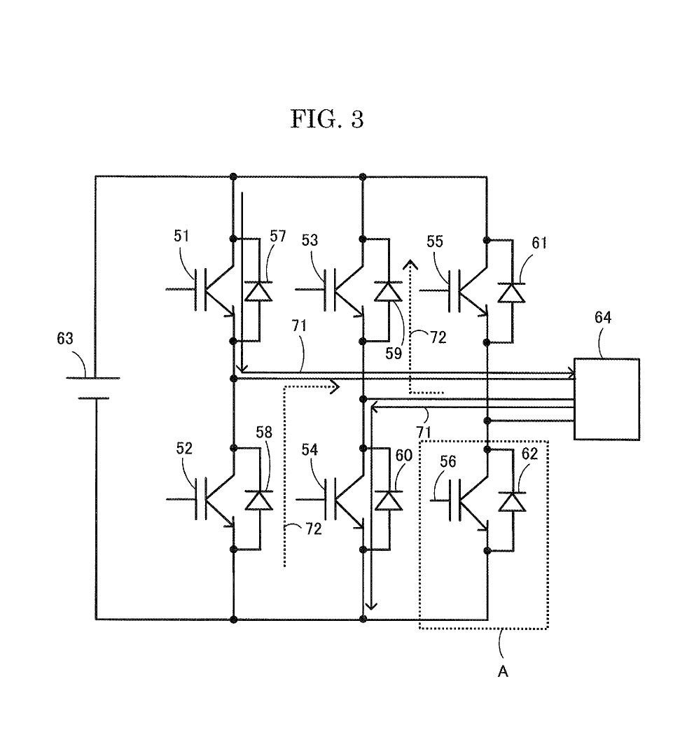

FIG. 3 is a diagram showing a three-phase inverter circuit. This inverter circuit includes six IGBTs 51 to 56 as voltage-driven type semiconductor devices, six FWDs (Free Wheeling Diode) 57 to 62, and a main power supply 63. An L load of a motor etc. is connected as a load 64 to the inverter circuit.

Operation of the inverter will be described. Assume that the IGBT 51 and the IGBT 54 turn ON at a certain timing so that a current 71 is supplied from the main power supply 63 to the load 64. When the IGBT 51 and the IGBT 54 then turn OFF, the current 71 flowing into the load 64 passes through the FWDs 58 and 59 and flows back as a return current to the main power supply 63. When the IGBTs 51 to 56 turn ON and OFF sequentially in this manner, three-phase electric power is supplied to the load 64.

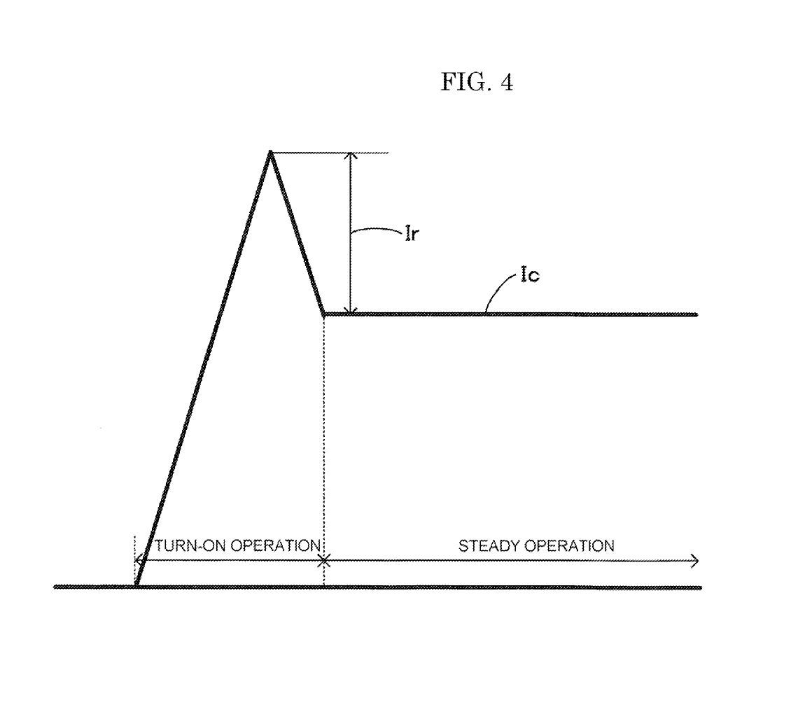

When the IGBT 51 changes from ON to OFF and the IGBT 54 turns ON in the state in which a current 72 is flowing into the FWD 59, a series circuit of the FWD 59 and the IGBT 54 becomes an arm short-circuiting state instantaneously. This arm short-circuiting is cancelled when the FWD 59 is reversely recovered. However, when the IGBT 54 turns ON, the reverse recovery current of the FWD 59 is superimposed on a collector current of the IGBT 54 and flows. For this reason, as shown in FIG. 4, the collector current Ic of the IGBT 54 increases suddenly because the reverse recovery current Ir is superimposed on the collector current Ic of the IGBT 54 when the IGBT 54 is operated to be turned ON. Then, the collector current Ic of the IGBT 54 shifts to a steady state.

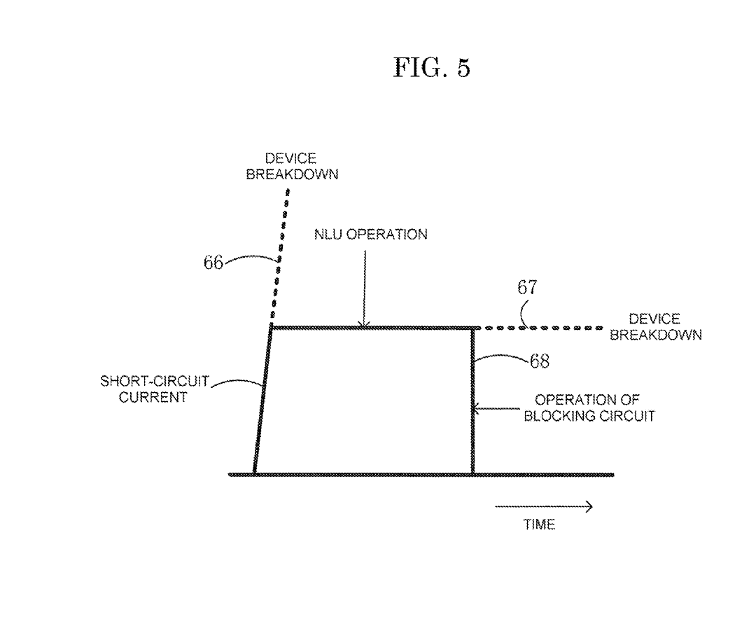

FIG. 5 is a diagram for explaining an operation state of the IGBT at the time of short-circuiting. When a short-circuit current 66 flows, device breakdown occurs. In order to prevent this, an NLU (Non-Latch-Up) circuit is operated to restrain the short-circuit current. However, when the time in which a restraint current 67 flows is prolonged, device breakdown occurs. In order to prevent this, a blocking circuit is operated to block the restraint current 67 (blocking current 68) as soon as the period in which the restraint current 67 flows (NLU operation period) exceeds a predetermined time to (for example, about 2 μs). In this manner, the device is protected from the short-circuit current. This circuit is a short-circuit protection circuit.

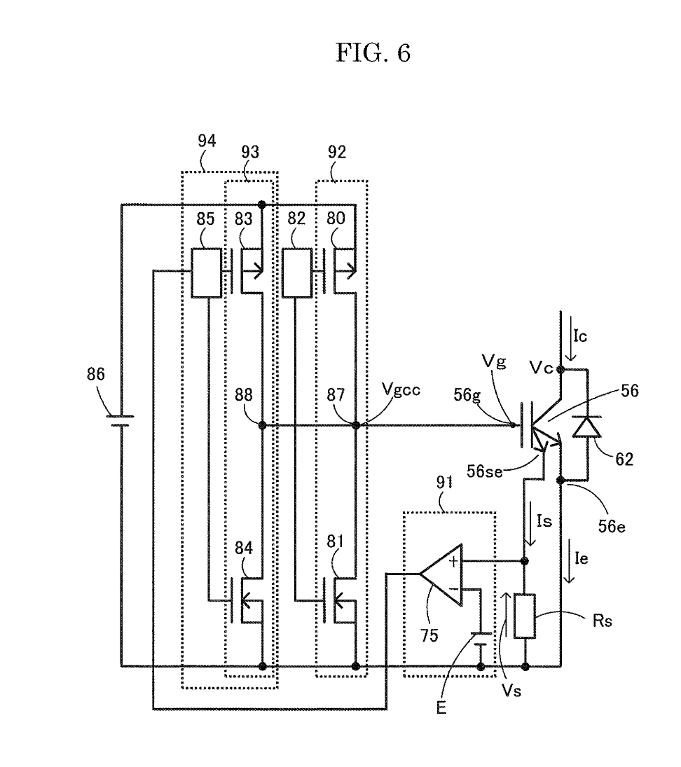

FIG. 6 is a diagram showing a short-circuit protection circuit for an IGBT according to the background art. In addition to the short-circuit protection circuit, an IGBT drive circuit is also shown in FIG. 6. In addition, FIG. 6 coincides with a circuit of a part corresponding to a portion A in FIG. 3.

The IGBT drive circuit driving the IGBT 56 includes a control power supply 86, a series circuit 92 of a p-channel MOSFET 80 and an n-channel MOSFET 81, and a drive circuit 82 driving gates of these MOSFETs 80 and 81. A contact point 87 between the p-channel MOSFET 80 and the n-channel MOSFET 81 is connected to a gate 56g of the IGBT 56. A control voltage Vgcc is applied to the gate 56g.

An NLU circuit 94 includes a series circuit 93 of a p-channel MOSFET 83 and an n-channel MOSFET 84, and a drive circuit 85 driving these MOSFETs 83 and 84. A contact point 88 between the p-channel MOSFET 83 and the n-channel MOSFET 84 is connected to the contact point 87. When the NLU circuit 94 is operated, a control power supply voltage VCC (for example, about 15V) of the control power supply 86 is reduced. This reduced voltage is applied as the control voltage Vgcc (for example, about 1V) to the gate 56g of the IGBT 56.

A detection circuit 91 is a circuit which activates the NLU circuit 94 upon detection of a short-circuit current. The detection circuit 91 includes an operational amplifier 75 and a reference power supply E. A high potential side of a sense resistor Rs is connected to a sense emitter 56se which is a current detection terminal of the IGBT 56. A low potential side of the sense resistor Rs is connected to a main emitter 56e. The high potential side of the sense resistor Rs is connected to a plus terminal of the operational amplifier 75. A minus terminal of the operational amplifier 75 is connected to a plus side of the reference voltage E. A minus side of the reference voltage E is connected to the low potential side of the sense resistor Rs. An output 78 of the operational amplifier 75 is connected to an input 79 of the drive circuit 85.

In addition, a sense current Is flows into the sense resistor Rs series-connected to the sense emitter 56se of the IGBT 56 into which a main current is applied. The operational amplifier 75 having the plus terminal to which the high potential side of the sense resistor Rs is connected and the minus terminal to which the low potential side (GND) of the sense resistor Rs is connected through the reference voltage E detects whether the IGBT 56 is in a short-circuit state or not, based on the magnitude of the sense current Is, so that the output 78 of the operational amplifier 75 is inputted to the NLU circuit 94. In addition, a freewheeling diode 62 is anti-parallel connected to the IGBT 56.

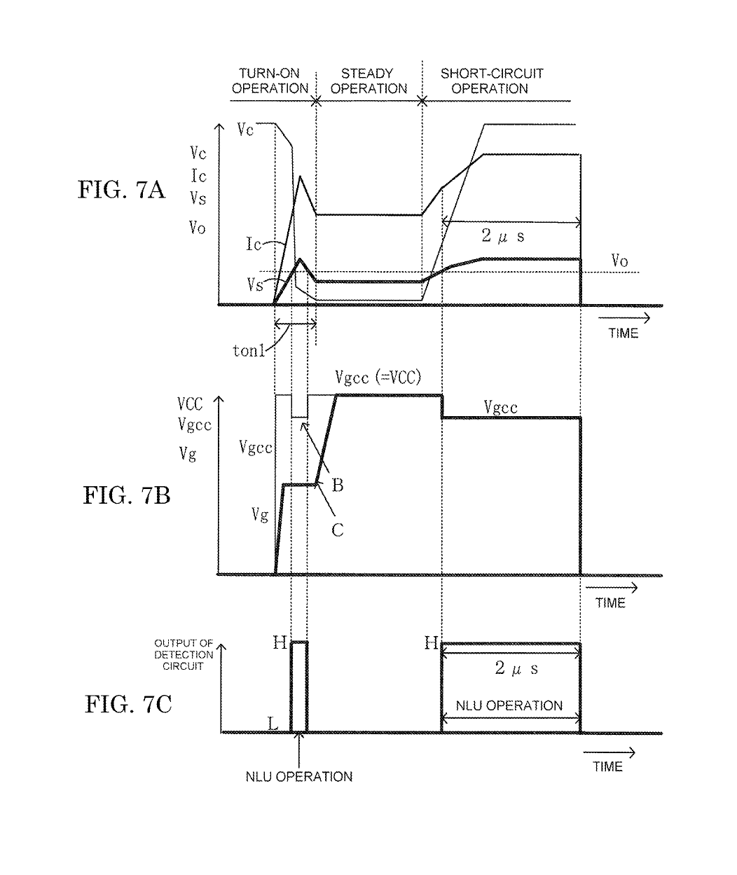

FIG. 7 shows operation waveform diagrams of respective portions in the circuit in FIG. 6 during turn-on operation, during steady operation, and during short-circuit operation. In FIG. 7, (a) is an operation waveform diagram of Vc, Ic and Vs, (b) is an operation waveform diagram of Vgcc and Vg, and (c) is a diagram showing an output of a mask circuit. In FIG. 7, the three modes are illustrated together for convenience of explanation. Here, the reference sign VCC designates voltage of the control power supply 86; Vgcc, control voltage; Vg, gate voltage of the IGBT 56; Vc, collector voltage of the IGBT 56; Ic, collector current of the IGBT 56; Ie, emitter current of the IGBT 56; Is, sense current flowing into the sense emitter of the IGBT 56; Vs, sense voltage generated in the sense resistor Rs; L, L level; H, H level; and ton1, turn-on time. Ic is split into Ie and Is.

First, a turn-on operation of the IGBT 56 will be described. When the p-channel MOSFET 80 in the IGBT drive circuit turns ON, the control voltage Vgcc equal to the voltage VCC (for example, about 15V) of the control power supply 86 is applied to the gate 56g of the IGBT 56.

A gate current flows into the gate 56g of the IGBT 56 to charge gate capacitance (gate-emitter capacitance in this case). When the gate capacitance is charged, the gate voltage Vg rises. When the gate voltage vg rises to reach a gate threshold voltage, the collector current Ic rises but the collector voltage Vc begins to fall.

In addition, the sense current Is which is about a several thousandth part of the collector current Ic rises, and a voltage at opposite ends of the sense resistor Rs into which the sense current Is flows, i.e. the sense voltage Vs also increases. When the gate voltage Vg reaches the gate threshold voltage, the collector voltage Vc decreases, mirror capacitance (gate-collector capacitance) of the IGBT 56 increases and the gate voltage vg shifts to a region where the gate voltage vg is substantially constant.

In addition, when the sense voltage Vs increases to reach an operation threshold voltage Vo (which is determined based on the reference voltage E) where the sense voltage Vs can be regarded as a short-circuit current, the output 78 of the detection circuit 91 outputs an L level signal so that the NLU circuit 94 operates.

The NLU circuit 94 turns ON the n-channel MOSFET 84 when the output 78 of the detection circuit 91 is on the L level. When the n-channel MOSFET 84 turns ON, a voltage of Vgcc is withdrawn to make the control voltage Vgcc of the contact point 87 lower than the control power supply voltage VCC, as indicated by the sign B. Incidentally, the current driving capability of the MOSFET 84 is set to be smaller than that of the MOSFET 80 so that the control voltage Vgcc can be prevented from being zero even when the MOSFET 84 turns ON.

When the control voltage Vgcc of the contact point 87 is lower than the control power supply voltage VCC, the collector current Ic and the sense voltage Vs reach their peaks, then pass through the operation threshold voltage Vo and decrease so that the operation of the NLU circuit 94 is cancelled. Then, the collector current Ic and the sense voltage Vs become constant. After the collector voltage Vc decreases suddenly in the period of time in which the NLU circuit 94 is operating, the collector voltage Vc decreases gradually and then shifts to a steady on-state voltage.

At a point of time (point C) in which the collector voltage Vc has become the steady on-state voltage which is sufficiently low, there is no change in the mirror capacitance any more, and the gate voltage Vg increases again to reach the control power supply voltage VCC (=the control voltage Vgcc) and then becomes constant.

As described above, when the NLU circuit 94 operates to reduce the control voltage Vgcc applied to the gate 56g in the period of time in which the mirror capacitance increases and the gate voltage Vg becomes constant, the supply of the current to the gate of the IGBT 56 becomes insufficient so that the time required until the voltage Vg reaches a desired value becomes longer, the falling of the collector voltage Vc becomes gentler, and the turn-on time ton1 becomes longer. Thus, a turn-on loss increases.

Next, a short-circuit operation of the IGBT will be described. When a short-circuit current flows into the IGBT 56 in the state in which the control power supply voltage VCC (=the control voltage Vgcc) is being applied to the gate 56g of the IGBT 56, the sense voltage Vs reaches the operation threshold voltage Vo so that the NLU circuit 94 operates. In addition, the collector voltage Vc increases toward a not-shown main circuit power supply voltage and then becomes a constant voltage. When the NLU circuit 94 operates, the control voltage Vgcc becomes lower than the control power supply voltage VCC and the collector current Ic (short-circuit current) is restrained. When the NLU operation continues for a predetermined period (for example, about 2 μs), a not-shown blocking circuit built in the drive circuit 82 operates so that the collector current Ic is blocked. That is, when the not-shown blocking circuit operates, the operation of the NLU circuit 94 is cancelled. Simultaneously with this, the MOSFET 80 in the IGBT drive circuit turns OFF and the MOSFET 81 turns ON, so that the control voltage Vgcc decreases suddenly and the collector current Ic is blocked.

In PTL 1, there has been disclosed a technique in which overcurrent detection is suspended in sync with an ON (OFF) signal command of a power semiconductor device for a predetermined period of time in order to prevent an overcurrent from being detected by mistake due to the sudden increase of a sense current when the power semiconductor device turns ON (OFF).

In addition, in PTL 2, there has been disclosed a technique in which comparison between an operation threshold voltage used for a transient state and a current detection value is made in the transient state immediate after turning-on of an IGBT, with a leading edge of an input signal used as a trigger, in order to prevent an overcurrent state from being detected by mistake due to the rising of a current detection waveform in a transient period immediately after the turning-on.

### CITATION LIST

### Patent Literature

PTL 1: JP-A-5-276761

PTL 2: JP-A-6-120787

### SUMMARY OF INVENTION

### Technical Problem

In FIG. 7, the ratio of the sense current Is to the collector current Ic is constant at the time of normal turn-on. However, when the collector current Ic increases to be close to a rated current, the ratio of the sense current Is to the collector current Ic becomes larger so that the sense voltage Vs becomes larger. It is presumed that this ratio becomes larger because the current flowing through the gate capacitance is also included in the current flowing into the sense resistor Rs. Therefore, when the IGBT 56 is operated to be turned ON with a current close to the rated current, the sense voltage Vs may increase to exceed the operation threshold voltage Vo operating the NLU circuit 94, as described above.

When the sense voltage Vs exceeds the operation threshold voltage Vo, the NLU circuit 94 operates instantaneously so that the voltage supplied from the control power supply 86 decreases. As a result, the gate current supplied to the gate 56g (gate capacitance) of the IGBT 56 is supplied insufficiently. As a result, the turn-on time ton1 of the collector voltage Vc of the IGBT 56 becomes longer and the falling of the turn-on voltage delays so that a turn-on loss increases.

In addition, PTL 1 and PTL 2 give no description about a technique in which a mask circuit is added to the NLU circuit 94 to prevent the NLU circuit from being operated at the time of turn-on so as to reduce a turn-on loss of an IGBT.

In order to solve the foregoing problems, an object of the invention is to provide a short-circuit protection circuit which has a mask circuit which can prevent an NLU circuit from being operated during turn-on operation of an IGBT so as to reduce a turn-on loss of the IGBT.

### Solution to Problem

In order to achieve the object, in a first aspect of the invention, there is provided a short-circuit protection circuit for preventing a voltage-controlled type semiconductor device from short-circuit breakdown. This short-circuit protection circuit has: an NLU circuit which changes a control voltage applied to a gate of the voltage-controlled type semiconductor device in order to prevent the voltage-controlled type semiconductor device from latch-up caused by a current flowing into the voltage-controlled type semiconductor device; and a mask circuit which sets the NLU circuit at a non-operating state when a current flowing into the voltage-controlled type semiconductor device is on a level to operate the NLU circuit during turn-on operation of the voltage-controlled type semiconductor device and a gate voltage of the voltage-controlled type semiconductor device is lower than the control voltage outputted to the gate of the voltage-controlled type semiconductor device from a control circuit of the voltage-controlled type semiconductor device when the NLU circuit operates.

In addition, in a second aspect of the invention, the mask circuit performs mask operation in the state in which a voltage applied to the gate of the voltage-driven type semiconductor device is lower than the control voltage and lower than a first operation threshold voltage which is a voltage applied to the gate of the voltage-driven type semiconductor device when the NLU circuit operates, so that the mask circuit sets the NLU circuit at a non-operating state.

In addition, in a third aspect of the invention, the mask circuit is provided with: a first comparison portion whose output turns to an H level when the voltage applied to the gate of the voltage-driven type semiconductor device is not lower than a first reference voltage set as the first operation threshold voltage; a second comparison portion whose output turns to an H level when a voltage on a high potential side of a current detection resistor series-connected to a current detection terminal of the voltage-driven type semiconductor device is not lower than a second reference voltage set as a second operation threshold voltage which is on a level in which a voltage generated in the current detection sense resistor can be regarded as short-circuiting of the voltage-driven type semiconductor device; and an AND circuit which takes a logical product of the output of the first comparison portion and the output of the second comparison portion.

### Advantageous Effects of Invention

In the invention, a mask circuit is provided so that operation of an NLU circuit is suspended during turn-on operation of a voltage-controlled type semiconductor device. Accordingly, the voltage-controlled type semiconductor device can be turned ON with a sufficient gate voltage so that a turn-on loss can be reduced.

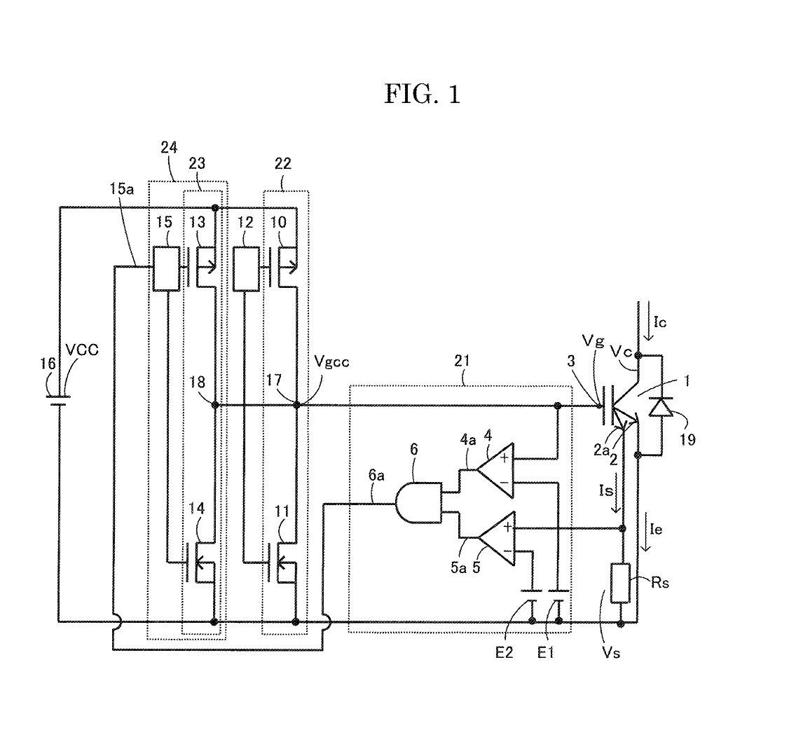

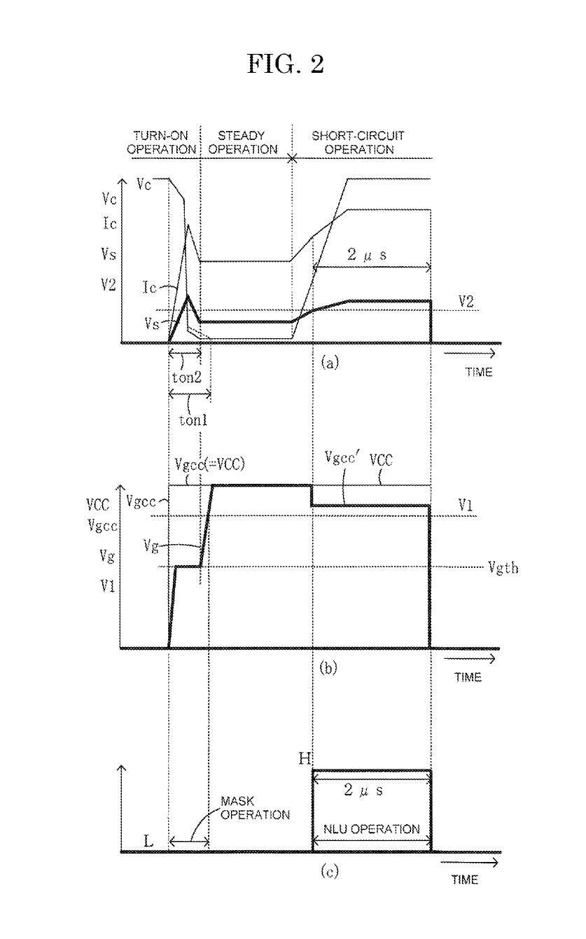

### BRIEF DESCRIPTION OF DRAWINGS

[FIG. 1] A circuit diagram showing a short-circuit protection circuit according to an example of the invention.

[FIG. 2] Operation waveform diagrams of respective portions in the circuit in FIG. 1 during turn-on operation, during steady operation, and during short-circuit operation, in which (a) is an operation waveform diagram of Vc, Ic, and Vs, (b) is an operation waveform diagram of Vgcc and Vg, and (c) is a diagram showing an output of a mask circuit.

[FIG. 3] A diagram of a three-phase inverter circuit.

[FIG. 4] A waveform diagram of an IGBT 54 during turn-on operation.

[FIG. 5] A diagram for explaining an operation state of the IGBT at the time of short-circuiting.

[FIG. 6] A diagram of a short-circuit protection circuit for an IGBT according to the background art.

[FIG. 7] Operation waveform diagrams of respective portions in the circuit in FIG. 6 during turn-on operation, during steady operation, and during short-circuit operation, in which (a) is an operation waveform diagram of Vc, Ic and Vs, (b) is an operation waveform diagram of Vgcc and Vg and (c) is a diagram showing an output of a mask circuit.

### DESCRIPTION OF EMBODIMENTS

An embodiment will be described in conjunction with an example as follows.

### Example

FIG. 1 is a circuit diagram of a short-circuit protection circuit according to an example of the invention. In addition to the short-circuit protection circuit, an IGBT drive circuit is also shown in FIG. 1. The short-circuit protection circuit is constituted by an NLU circuit 24, a mask circuit 21 and a not-shown blocking circuit.

In FIG. 1, the reference sign 1 designates an IGBT (Insulated Gate Bipolar Transistor) which is a voltage-controlled type semiconductor device. The IGBT drive circuit which drives the IGBT 1 includes a control power supply 16, a series circuit 22 of a p-channel MOSFET 10 and an n-channel MOSFET 11 connected to a plus side and a minus side of the control power supply 16, and a drive circuit 12 driving these MOSFETs 10 and 11. A contact point 17 between the p-channel MOSFET 10 and the n-channel MOSFET 11 is connected to a gate 3 of the IGBT 1. A voltage of the contact point 17 is supplied as a control voltage Vgcc to the gate 3 of the IGBT 1.

The NLU circuit 24 includes a series circuit 23 of a p-channel MOSFET 13 and an n-channel MOSFET 14 connected to the plus side and the minus side of the control power supply 16, and a drive circuit 15 driving these MOSFETs 13 and 14. A contact point 18 between the p-channel MOSFET 13 and the n-channel MOSFET 14 is connected to the contact point 17. When the NLU circuit 24 operates, a control power supply voltage VCC of the control power supply 16 in the contact point 18 is reduced. This reduced voltage is supplied as the control voltage Vgcc to the gate 3 of the IGBT 1.

The mask circuit 21 is provided with a first comparator 4 as a first comparison portion constituted by an operational amplifier, a second comparator 5 as a second comparison portion likewise constituted by an operational amplifier, and an AND circuit 6.

The gate 3 of the IGBT 1 is connected to a plus terminal of the first comparator 4. A plus side of a first reference voltage El is connected to a minus terminal of the first comparator 4. Accordingly, when a gate voltage Vg of the IGBT 1 is lower than the first reference voltage E1, an output of the first comparator 4 turns to an L level. When the gate voltage Vg is not lower than the first reference voltage E1, the output of the first comparator 4 turns to an H level.

A sense emitter 2a which is a current detection terminal of the IGBT 1 is connected to one end (high potential side) of a sense resistor Rs. The sense emitter 2a outputs a current (about a ten-thousandth part of a current of a main emitter 2) proportional to the current flowing into the main emitter 2. The sense emitter 2a is formed simultaneously when an emitter region of the IGBT 1 is formed.

The high potential side of the sense resistor Rs is connected to a plus terminal of the second comparator 5. A plus side of a second reference voltage E2 is connected to a minus terminal of the second comparator 5. Accordingly, when a sense voltage Vs on the high potential side of the sense resistor Rs is lower than the second reference voltage E2, an output of the second comparator 5 turns to an L level. When the sense voltage Vs is not lower than the second reference voltage E2, the output of the second comparator 5 turns to an H level.

An output 4a of the first comparator 4 and an output 5a of the second comparator 5 are connected to an input side of the AND circuit 6.

Here, a minus side of the first reference voltage E1 and a minus side of the second reference voltage E2 are connected to a low potential side of the sense resistor Rs. That is, the main emitter 2, the low potential side of the sense resistor Rs, the minus side of the first reference voltage E1, and the minus side of the second reference voltage E2 are connected to the minus side of the control power supply 16.

In addition, an output 6a side of the AND circuit 6 is connected to an input 15a side of the NLU drive circuit 15. Incidentally, a freewheeling diode 19 is anti-parallel connected to the IGBT 1.

FIG. 2 shows operating waveform diagrams of respective portions in the circuit in FIG. 1 during turn-on operation, during steady operation, and during short-circuit operation. In FIG. 2, (a) is an operating waveform diagram of Vc, Ic and Vs, (b) is an operating waveform diagram of Vgcc and Vg, and (c) is a diagram showing an output of the mask circuit 21. Here, the reference sign VCC designates voltage of the control power supply 16; Vgcc, control voltage of the contact point 17; Vgcc′, limit control voltage when the NLU circuit 24 operates; Vg, gate voltage (gate-emitter voltage); Vc, collector voltage (collector-emitter voltage) of the IGBT 1; Ic, collector current of the IGBT 1; Ie, emitter current of the IGBT 1; Is, sense current of the IGBT 1; Vs, sense voltage of the IGBT 1; L, L level; H, H level; ton1, turn-on time according to the background art; tong, turn-on time according to the invention; V1, first operation threshold voltage; V2, second operation threshold voltage; and Vgth, gate threshold voltage. The collector current Ic is split into the emitter current Ie and the sense current Is.

Next, operation of the circuit in FIG. 1 will be described. First, a turn-on operation of the IGBT 1 will be described. When the p-channel MOSFET 10 turns ON in the state in which the n-channel MOSFET 11 is OFF so that the control power supply voltage VCC (about 15V) of the control power supply 16 is supplied as the control voltage Vgcc to the gate 3 of the IGBT 1, the gate voltage Vg of the IGBT 1 rises, as shown in (b) of FIG. 2. When the gate voltage Vg rises to reach the gate threshold voltage (voltage with which a channel can be formed in the IGBT 1), the collector current Ic rises but the collector voltage Vc falls, as shown in (a) of FIG. 2.

In addition, the sense current Is which is about a several thousandth part to a several ten-thousandth part of the collector current Ic rises so that the sense current Is is applied to the sense resistor Rs. The sense voltage Vs (sense current Is X sense resistor Rs) which is generated because the sense current Is is applied to the sense resistor Rs also increases.

When the gate voltage Vg reaches the gate threshold voltage Vgth, the gate voltage Vg shifts to a constant region due to mirror capacitance (gate-collector capacitance). In this state, the gate voltage Vg has not reached the first operation threshold voltage V1 which has been set in advance. The first operation threshold voltage V1 depends on the first reference voltage E1. When the gate voltage Vg reaches the first operation threshold voltage V1, the output 4a of the first comparator 4 turns to an H level (which is the control power supply voltage VCC of the control power supply 16 in this case).

The control power supply voltage VCC is converted into the voltage of the contact point 17 between the p-channel MOSFET 10 and the n-channel MOSFET 11 in the gate drive circuit and outputted as the control voltage Vgcc to the gate 3 of the IGBT 1. In the case where the NLU circuit 24 does not operate, the control voltage Vgcc coincides with the control power supply voltage VCC. For example, the control voltage Vgcc is about 15V. On the other hand, in the case where the NLU circuit 24 operates, the control power supply voltage VCC is withdrawn by the n-channel MOSFET 14 of the NLU circuit 24 so that the voltage decreases to the limit control voltage Vgcc′ lower than the control power supply voltage Vcc. The limit control voltage Vgcc′ when the NLU circuit 24 operates is, for example, about 13V.

The first operation threshold voltage V1 is set to be lower than the aforementioned limit control voltage Vgcc′ (for example, about 13V) and higher than the gate threshold voltage Vgth.

In addition, the sense voltage Vs increases to reach the second operation threshold voltage V2 which has been determined in advance, as shown in (a) of FIG. 2. The second operation threshold voltage V2 is a sense voltage Vs which can be regarded as a short-circuit current. This second operation threshold voltage V2 is set as the second reference voltage E2. The second reference voltage E2 is, for example, about 4V. When the sense voltage Vs reaches the second operation threshold voltage V2 (=the second reference voltage E2), the output 5a of the second comparator 5 turns to an H level (the control power supply voltage VCC in this case).

In the state in which the gate voltage Vg has not reached the first operation threshold voltage V1, the output 4a of the first comparator 4 is on an L level (GND in this case). Both this L level and the H level of the output 5a of the second comparator 5 are inputted to the AND circuit 6. The L level (GND in this case) is outputted from the output 6a of the AND circuit 6. The output of the AND circuit 6 becomes an output of the mask circuit 21, which is supplied to the drive circuit 15 of the NULL circuit 24.

Here, the first and second comparators 4 and 5 are operated by the control power supply 16 which is a power supply for operating the mask circuit 21.

Since the output 6a of the AND circuit 6 is on the L level, the operation of the NLU circuit 24 is suspended (non-operating state). That is, even when the sense voltage Vs exceeds the second operation threshold voltage V2 in the state in which the gate voltage Vg is lower than the first operation threshold voltage V1, the mask circuit 21 performs mask operation (which means the state in which the output 6a of the AND circuit 6 is on the L level) so that the operation of the NLU circuit 24 is suspended (the NLU circuit 24 is in a non-operating state). The first operation threshold voltage V1 is a gate voltage Vg which can be regarded as a short-circuit current. The second operation threshold voltage V2 is a sense voltage Vs which can regarded as a short-circuit current.

Next, at a point of time in which the gate voltage Vg passes through the constant region and then increases again to reach the first operation threshold voltage V1, the output 4a of the first comparator 4 turns to an H level. On the other hand, the collector current Ic and the sense voltage Vs pass through their peaks and then decrease. The sense voltage Vs becomes not higher than the second operation threshold voltage V2 so that the output 5a of the second comparator 5 turns to an L level. When both an H level output signal of the first comparator 4 and an L level output signal of the second comparator 5 are inputted to the AND circuit 6, the output 6a of the AND circuit 6 maintains the L level. Since the output of the AND circuit 6 is on the L level, the operation of the NLU circuit 24 is kept suspended (non-operating state).

In the period of time in which the gate voltage Vg is in the constant region, the collector voltage Vc decreases and then shifts to a steady on-state voltage, as shown in (a) of FIG. 2. In the steady operation, the NLU circuit 24 is not operated.

As described above, during the turn-on operation, the operation of the NLU circuit 24 is suspended (non-operating state) by the mask operation of the mask circuit 21 so that the NLU circuit 24 does not operate. Therefore, the control power supply voltage VCC is applied as the control voltage Vgcc to the gate 3 of the IGBT 1 so that the drive of the IGBT 1 becomes sufficient to thereby accelerate the falling of the collector voltage Vc. As shown in (a) of FIG. 2, the turn-on time tong is shorter than the turn-on time ton1 of the background-art case. Therefore, a turn-on loss is reduced.

Next, a short-circuit operation of the IGBT 1 will be described. In a short-circuit state, the gate voltage Vg rises, and the short-circuit current, that is, the collector current Ic increases. Therefore, the sense voltage Vs also increases. Since the gate voltage Vg reaches the first operation threshold voltage V1 in a steady state, the output 4a of the first comparator 4 turns to an H level. On the other hand, since the sense voltage Vs has not reached the second operation threshold voltage V2, the output 5a of the second comparator 5 is on an L level. Therefore, the output 6a of the AND circuit 6 turns to an L level. Since the output of the AND circuit 6 is on the L level, the NLU circuit 24 does not operate.

When the sense voltage Vs then increases to reach the second operation threshold voltage V2, the output 5a of the second comparator 5 turns to an H level so that an H level is outputted from the AND circuit 6. In this manner, the NLU circuit 24 operates so that the control power supply voltage VCC is withdrawn by the n-channel MOSFET 14 to reduce the gate voltage Vg to the limit control voltage Vgcc′. However, since the limit control voltage Vgcc′ is set to be higher than the first operation threshold voltage V1, the output 4a of the first comparator 4 maintains the H level.

When the sense voltage Vs reflecting the collector current Ic exceeds the second operation threshold voltage V2 for a predetermined period (for example, about 2 μs), the not-shown blocking circuit built in the short-circuit protection circuit operates to forcibly reduce the gate voltage Vg and block a gate signal to the IGBT 1. As a result, the short-circuit current is narrowed, and the IGBT 1 is blocked. The not-shown blocking circuit may be built in the drive circuit 12.

Even when the mask circuit 21 is added as described above, the mask operation of the mask circuit 21 is cancelled in the period of time in which the short-circuit current flows so that the NLU circuit 24 operates. Accordingly, latch-up does not occur in the IGBT 1 so that the IGBT 1 can be blocked surely against breakdown in the same manner as the short-circuit protection circuit according to the background art. Thus, the NLU circuit 24 is operated in the same manner as in the background art during short-circuit operation of the IGBT 1 so that device breakdown caused by the short-circuit current can be prevented.

In addition, when not the short-circuit current but an overcurrent flows into the IGBT 1, an overcurrent protection circuit not shown is often operated to protect the IGBT 1 from breakdown. In this case, the level of the sense voltage Vs which can be regarded as an overcurrent is set to be lower than a level which can be regarded as a short-circuit current. Also when the overcurrent flows, a gate signal is suspended so that the IGBT 1 is blocked forcibly.

Incidentally, although not shown, in the case where the IGBT 1 is blocked forcibly, normally, so-called software blocking is performed to make the falling of the current gentle enough to suppress noise etc. generated at that time.

In addition, although the IGBT 1 is exemplified as a voltage-driven type semiconductor device in the example, the invention may be also applied to another voltage-driven type semiconductor device such as a power MOSFET made of a wide gap semiconductor substrate of SiC etc.

### INDUSTRIAL APPLICABILITY

According to the invention, it is possible to provide a short-circuit protection circuit which can reduce a turn-on loss of a voltage-controlled type semiconductor device in such a manner that an NLU circuit is prevented from being operated by a mask circuit during turn-on operation of the voltage-driven type semiconductor device.

### REFERENCE SIGNS LIST

1 IGBT

2 main emitter

2a sense emitter

3 gate

4 first operational amplifier

4a, 5a, 6a, 7a output

5 second operational amplifier

6 AND circuit

10, 13 p-channel MOSFET

11, 14 n-channel MOSFET

12, 15 drive circuit

15a input

16 control power supply

17, 18 contact point

21 mask circuit

22, 23 series circuit

24 NLU circuit

VCC control power supply voltage

Vgcc control voltage

Vg gate voltage

Rs sense resistor

Vs sense voltage

Vc collector voltage

Is sense current

Ic collector current

Ie emitter current

V1 first operation threshold voltage

V2 second operation threshold voltage

E1 first reference voltage

E2 second reference voltage

1. A short-circuit protection circuit for protecting a voltage-driven semiconductor device from short-circuit breakdown, comprising:
a control circuit for generating a control voltage that is applied to a gate of the voltage-driven semiconductor device
an NLU (Non-Latch-Up) circuit which changes the control voltage in order to prevent the voltage-driven semiconductor device from latching-up due to a current flowing into the voltage-driven semiconductor device; and
a mask circuit which sets the NLU circuit at a non-operating state when the current flowing into the voltage-driven semiconductor device is at a level to operate the NLU circuit during a turn-on operation of the voltage-driven semiconductor device but a gate voltage of the voltage-driven semiconductor device is lower than a first reference voltage.

2. The short-circuit protection circuit according to claim 1, wherein the mask circuit comprises:
a current detection resistor that is series-connected to a current detection terminal of the voltage-driven semiconductor device;
a first comparison portion whose output turns to an L level when the gate voltage applied to the gate of the voltage-driven semiconductor device is lower than the first reference voltage;
a second comparison portion whose output turns to an H level when a sense voltage on a high potential side of the current detection resistor is not lower than a second reference voltage; and
an AND circuit which takes a logical product of the output of the first comparison portion and the output of the second comparison portion.

3. The short-circuit protection circuit according to claim 2, wherein:
the first reference voltage is set to be higher than a gate threshold voltage of the voltage-driven semiconductor device;
the second reference voltage is set at a level in which a voltage generated across the current detection sense resistor is indicative of a short-circuiting of the voltage-controlled semiconductor device; and
the mask circuit performs a mask operation where the gate voltage applied to the gate of the voltage-controlled semiconductor device is lower than the first reference voltage so as to set the NLU circuit at a non-operating state.

4. The short-circuit protection circuit according to claim 1, wherein the voltage-driven semiconductor device is an insulated gate bipolar transistor.
